(19) United States
(12) Patent Application Publication
(10) Pub. No.: US 2025/0054914 A1
(43) Pub. Date: Feb. 13, 2025

(54) METHOD OF ALIGNMENT OF ELECTRICAL COMPONENTS OF AN ELECTRICAL APPARATUS WITH A SUPPORT ASSEMBLY

(71) Applicant: Microchip Technology Incorporated, Chandler, AZ (US)

(72) Inventor: Mankit Lam, Colorado Springs, CO (US)

(21) Appl. No.: 18/585,944

(22) Filed: Feb. 23, 2024

Related U.S. Application Data
(60) Provisional application No. 63/519,182, filed on Aug. 11, 2023.

(51) Int. Cl. H01L 25/065; H01L 23/00

(52) U.S. Cl. CPC H01L 25/0657; H01L 24/10; H01L 24/16; H01L 24/81; H01L 2224/10135; H01L 2224/16148; H01L 2224/81007; H01L 2224/81143; H01L 2224/81815; H01L 2225/06513; H01L 2225/06593; H01L 2924/381

(57) ABSTRACT

An apparatus includes first electrical components, wherein a respective first electrical component has first connection areas, and second electrical components, wherein a respective second electrical component has second connection areas. The apparatus also includes support structures, wherein a respective support structure is mounted to a respective first electrical component to limit a lateral range of movement of a respective second electrical component relative to the respective first electrical component. The apparatus further includes masses of connection material to at least partially connect corresponding ones of the first connection areas of the first electrical components and the second connection areas of the second electrical components.

### CROSS-REFERENCE TO RELATED APPLICATION

This application claims the benefit under 35 U.S.C. § 119(e) of the priority date of U.S. Provisional Patent Application Ser. No. 63/519,182, filed Aug. 11, 2023, for SYSTEM FOR MASS REFLOW HETEROGENEOUS INTEGRATION OF ELECTRICAL SUBCOMPONENTS, the disclosure of which is incorporated herein in its entirety by this reference.

### FIELD

Examples relate to a method of alignment of electrical components of an electrical apparatus with a support assembly, and in particular, a method of face-to-face alignment of electrical components from different manufacturers and/or having different wafer nodes and/or functions with support assemblies prior to connection to one another in a mass reflow process.

### BACKGROUND

Heterogeneous integration uses packaging technology to integrate different chips, chiplets, dies and/or other electrical components from different manufacturers and/or having different sizes and/or features on different substrates, i.e., different wafer nodes and/or functions. Electrical components (e.g., chips, chiplets, dies, wafers) can include high numbers of connection points (e.g., hundreds, thousands). These connection points are of small geometry and pitch (e.g., microns), which pose assembly challenges.

In cases where the connections have critical electrical requirements, the common approach is to perform a face-to-face connection to minimize the distance and reduce resistance. Two approaches for face-to-face heterogeneous integration for the assembly (e.g., connection) of electrical components (e.g., chips, chiplets, dies, wafers) include a hybrid bonding process for high end, ultra-fine integration (e.g., less than about a 10-micron pitch), and a micro-copper pillar bumping process where larger pitches are present (e.g., less than about a 40-micron pitch).

Hybrid bonding processes (e.g., Cu—Cu, no solder) are expensive and difficult to implement. Alternatively, micro-copper pillar bumping processes employ solder reflow, which is more openly practiced where larger pitches are acceptable (e.g., less than about a 40-micron pitch). Micro-copper pillar bumping processes utilize high precision pick-and-place equipment where, typically, solder reflow connections occur at the “place” step, one unit at a time, as the pick tool remains intact to limit die movement during solder reflow. As a result of the pick tool remaining intact, the “self-aligning” benefit of the liquified solder is lost. Furthermore, throughput is severely limited as this process is implemented on a unit-by-unit basis, such that the process is not applicable to a mass reflow operation.

Attempts at mass reflow for ultra-fine pitch heterogeneous integration have been unreliable due to solder shorting at electrical connection points. This is due in part to uneven solder melt during reflow. This uneven solder melt results in varied surface tensions across the faces of the electrical components as the solder is in varied stages of liquification during the heating and cooling processes, causing unwanted and/or uneven movement of the electrical components, and the numerous solder joints being formed, relative to one another during the reflow process. In addition, even minor vibrations during transport of the electrical components into, through and from the heating zone can result in unwanted and/or uneven movement of the electrical components, and the numerous solder joints being formed, relative to one another.

### BRIEF SUMMARY

In some examples, an apparatus includes first electrical components, wherein a respective first electrical component has first connection areas, and second electrical components, wherein a respective second electrical component has second connection areas. The apparatus also includes support assemblies, wherein a respective support assembly is mounted to a respective first electrical component to limit a lateral range of movement of a respective second electrical component relative to the respective first electrical component. The apparatus further includes masses of connection material formed on at least one of the first connection areas or the second connection areas to at least partially connect corresponding ones of the first connection areas and the second connection areas.

In other examples, a method includes providing first electrical components, wherein a respective first electrical component includes first connection areas disposed thereon in a first connection array; mounting a respective support assembly to respective ones of the first electrical components, wherein the respective support assembly is mounted to the respective first electrical component in an at least partially surrounding relation to the first connection areas disposed thereon in the first connection array; providing second electrical components, wherein a respective second electrical component includes second connection areas disposed thereon in a second connection array; forming masses of connection material on one or both of the first electrical components or the second electrical components; positioning the second electrical components onto corresponding ones of the first electrical components in an aligned face-to-face orientation such that corresponding ones of the second connection areas are facing and substantially aligned with corresponding ones of the first connection areas, wherein positioning is at least partially defined by the respective support assembly of the respective first electrical component limiting a lateral range of movement of the respective second electrical component positioned thereon; liquifying the masses of connection material in a mass reflow process; and, cooling the liquified masses of connection material to form connections between corresponding ones of the first connection areas and the second connection areas.

In some other examples, an apparatus includes a first electrical component having first connection areas arranged thereon in a first connection array, and a second electrical component having second connection areas arranged thereon in a second connection array, the second electrical component positioned on the first electrical component such that the second connection areas are substantially aligned with corresponding ones of the first connection areas. The apparatus also includes a support assembly mounted to the first electrical component in an at least partially surrounding relation to the first connection areas in the first connection array, the support assembly limiting a lateral range of movement of the second electrical component positioned on the first electrical component. The apparatus further includes connections between corresponding ones of the first connection areas and the second connection areas formed from masses of connection material on one or both of the first connection areas or the second connection areas.

### BRIEF DESCRIPTION OF THE DRAWINGS

While this disclosure concludes with claims particularly pointing out and distinctly claiming specific examples, various features and advantages of examples within the scope of this disclosure may be more readily ascertained from the following description when read in conjunction with the accompanying drawings. In the drawings:

FIG. 1A presents a top plan view of a first electrical component of an electrical apparatus, in accordance with examples of the disclosure;

FIG. 1B presents a side elevation of the first electrical component of FIG. 1A, in accordance with examples of the disclosure;

FIG. 2A presents a top plan view of a second electrical component of an electrical apparatus, in accordance with examples of the disclosure;

FIG. 2B presents a side elevation of the second electrical component of FIG. 2A, in accordance with examples of the disclosure;

FIG. 3 presents a side elevation of a second electrical component prior to placement onto a first electrical component of an electrical apparatus, in accordance with examples of the disclosure;

FIG. 4A presents a top plan view of the second electrical component of FIG. 3 after placement onto the first electrical component in an aligned face-to-face orientation, in accordance with examples of the disclosure;

FIG. 4B presents a side elevation of the second electrical component of FIG. 3 after placement onto the first electrical component in an aligned face-to-face orientation, in accordance with examples of the disclosure;

FIG. 5 presents a side elevation of an electrical apparatus having electrical components aligned and connected with one another via a support assembly, in accordance with examples of the disclosure; and

FIG. 6 presents a flowchart of a method of alignment of electrical components of an electrical apparatus with a support assembly, in accordance with examples of the disclosure.

### DETAILED DESCRIPTION

The illustrations presented in this disclosure are not meant to be actual views of any method of alignment of electrical components of an electrical apparatus with a support assembly, or components thereof, but are merely idealized representations employed to describe illustrative examples. Thus, the drawings are not necessarily to scale.

As used herein, the terms “substantially” and “about” in reference to a given parameter, property, or condition means and includes to a degree that one of ordinary skill in the art would understand that the given parameter, property, or condition is met with a degree of variance, such as within acceptable manufacturing tolerances. For example, a parameter that is substantially or about a specified value may be at least about 90% the specified value, at least about 95% the specified value, at least about 99% the specified value, or even at least about 99.9% the specified value.

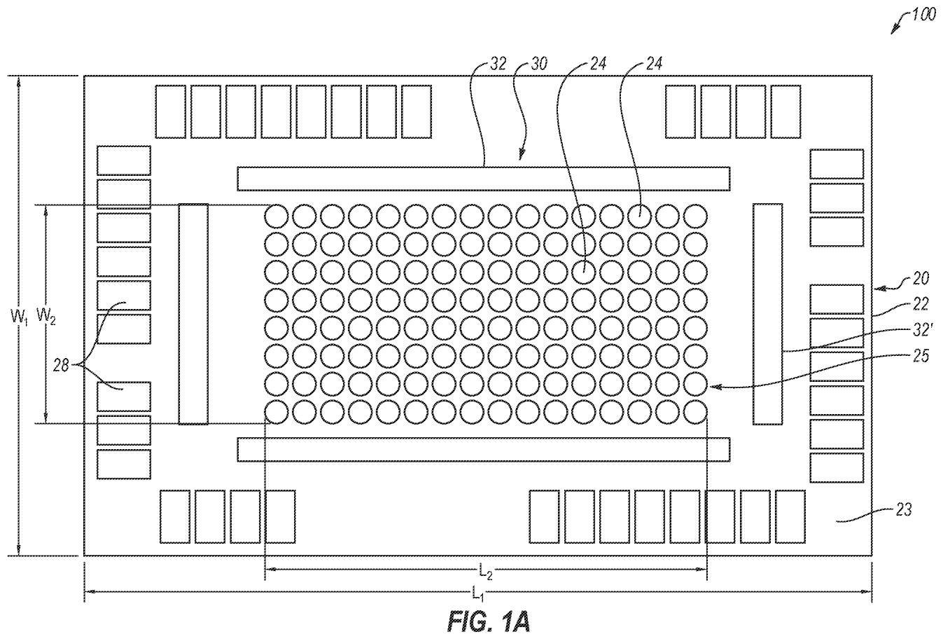

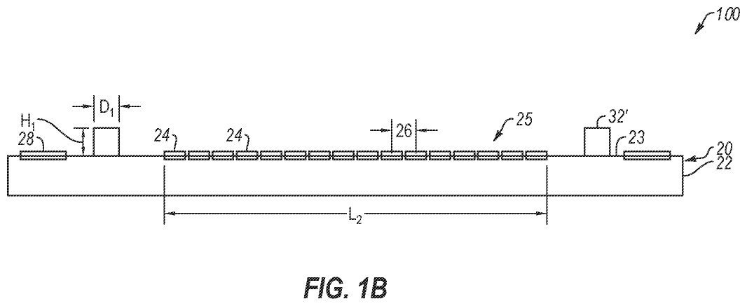

With reference first to FIGS. 1A and 1B, presented therein are a top plan view and a side elevation, respectively, of a first electrical component 20 of an electrical apparatus 100, in accordance with examples of the disclosure. First electrical component 20 in accordance with examples of the disclosure may include, but is in no manner limited to, chips, chiplets, dies, or wafers, without limitation. In some examples, first electrical component 20 may include, but is in no manner limited to, an analog electrical component (e.g., an analog chip, an analog chiplet, an analog die, an analog wafer).

The first electrical component 20 includes a first electrical component substrate 22, wherein the first electrical component substrate 22 may include any suitable material for electrical components (e.g., silicon). As shown in FIGS. 1A and 1B, the first electrical component substrate 22 includes a first substrate surface 23.

The first electrical component 20 may include any number of geometric configurations suitable for electrical components (e.g., square, rectangular, triangular, circular, semi-circular, or oval, without limitation). In some examples, such as is shown in FIG. 1A, the first electrical component 20 has a generally rectangular configuration and is at least partially defined by a first length L₁ and first width W₁ of the first electrical component substrate 22.

With continued reference to FIG. 1A, the first electrical component 20 includes a number of first connection areas 24 arranged on the first substrate surface 23 of the first electrical component substrate 22, forming a first connection array 25 thereon. The first connection array 25 may include a large number of first connection areas 24 (e.g., hundreds of first connection areas 24, to thousands of first connection areas 24, without limitation). In some examples, the first connection array 25 may be at least partially defined by a second length L₂ and a second width W₂, wherein the second length L₂ and second width W₂ are measured along the perimeter of the area on the first substrate surface 23 encompassing the first connection areas 24 comprising first connection array 25. In some examples, wherein the first connection array 25 has a different geometric configuration, alternative dimensions may at least partially define the first connection array 25 (e.g., diameter).

The first connection array 25 may be further defined by a first connection area pitch 26, wherein the first connection area pitch 26 is the distance between the centerpoints of adjacent ones of the first connection areas 24, such as is shown by way of example in FIG. 1B. In some examples, the first connection area pitch 26 may range from about 0.5 micrometers (μm) to about 1.0 millimeter (mm), such as from about 1.0 μm to about 0.5 mm, or from about 5.0 μm to about 0.05 mm, or from about 10.0 μm to about 40.0 μm. In some other examples, the first connection area pitch 26 may be less than about 100 μm, or less than about 50 μm, or less than about 40 μm, or less than about 20 μm, or less than about 10 μm, or less than about 1 μm. In some examples, the first connection area pitch 26 may be a very fine pitch (e.g., about a 25 μm pitch (e.g., a line width of about 12.5 μm and a line spacing of about 12.5 μm, or about 12.5 L/12.5S)).

In some examples, the first connection areas 24 may be formed of a metal (e.g., aluminum, copper). In other examples, exposed features of the first connection areas 24 are coated with a bondable and solderable material, such as one or more metals (e.g., a solderable silver layer about 1.0 μm thick over a nickel layer about 0.3 μm thick, which acts as a diffusion barrier, over a titanium layer about 0.1 μm thick, which adheres to the first connection areas 24).

An electrical apparatus 100 in accordance with examples of the disclosure includes a support assembly 30. A support assembly 30 may be mounted to a portion of a first electrical component 20. As may be seen from FIG. 1A, the support assembly 30 is mounted onto the first substrate surface 23 of the first electrical component 20. In some examples, the support assembly 30 includes one or more support structures 32, 32′ which may be formed on the first substrate surface 23 of the first electrical component 20. More specifically, the support assembly 30 may include one or more support structures 32, 32′ formed on the first substrate surface 23 of the first electrical component 20 in an at least partially surrounding relation to the first connection areas 24 in the first connection array 25.

As shown in FIG. 1A, the support assembly 30 includes support structures 32 mounted along and proximal to the second lengths L₂ of the first connection array 25, and support structures 32′ mounted along and proximal to the second widths W₂ of the first connection array 25. With reference to FIG. 1B, the support structures 32, 32′ are at least partially defined by a first height H₁, which is a distance from the first substrate surface 23 to the upper surfaces of the support structures 32, 32′. In some examples, the first height H₁ of the support structures 32, 32′ may be from about 5 μm to about 50 μm, such as from about 10 μm to about 40 μm, or from about 20 μm to about 30 μm, or about 20 μm. With continued reference to FIG. 1B, the support structures 32, 32′ are further defined by a first depth D₁, which is a distance between opposing sidewalls of the support structures 32, 32′, when viewed orthogonally to the first height and the length of the support structures 32, 32′. In other words, the first depth D₁ defines the width of the support structures 32, 32′. There is no requirement that the first depth D1 of the support structures 32, 32′ be uniform. In some examples, the first height H₁ of the support structures 32, 32′ may be greater that the first depth D₁ of the support structures 32, 32′, as may be seen from FIG. 1B. In other examples, the first depth D₁ may be greater than the first height H₁ of the support structures 32, 32′. In at least one example, the first height H₁ and the first depth D₁ of the support structures 32, 32′ are approximately equal.

The support structures 32, 32′ of a support assembly 30 may be constructed of any number of materials which exhibit structural integrity at the elevated temperatures to which the support structures 32, 32′ will be exposed during a mass reflow process, such as heating to temperatures of up to about 240° C., or up to about 260° C., or up to about 300° C., or up to about 400° C. for time periods of from about 0.1 minute to about 3 minutes, and subsequent cooling to ambient temperatures, or below. In some examples, the mass reflow process will be conducted at temperatures of from about 240° C. to about 260° C. for time periods of from about 0.1 minute to about 3 minutes. In addition, the material of construction of the support structures 32, 32′ may be substantially electrically inert and chemically inert, so as not to interfere with the normal operation of an electrical apparatus 100 in accordance with examples of the disclosure. In some examples, the support structures 32, 32′ may be formed of a polymeric material. As one example, the support structures 32, 32′ may be constructed of a photodefinable polymer, such as a photodefinable polyimide (e.g., HD4110 photodefinable polyimide by HD Microsystems, a joint venture of Showa Denko K.K. and DuPont de Nemours, Inc.). In some examples, the support structures 32, 32′ are formed of a single layer of a photodefinable polymer having a first height H₁ of about 20 μm after cure.

The first electrical component 20, in some examples, includes a number of wire bond pads 28 to facilitate electrical connections for operation thereof. With reference again to FIGS. 1A and 1B, the first electrical component 20 includes the number of wire bond pads 28 positioned around the outer permitter of the first electrical component substrate 22 of the first electrical component 20, and outside of the area defined by the first connection array 24, and outside of an area defined by the support structures 32, 32′.

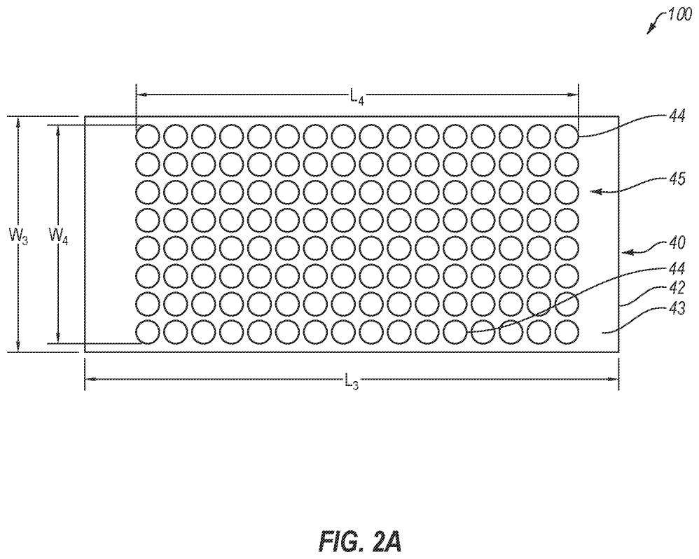

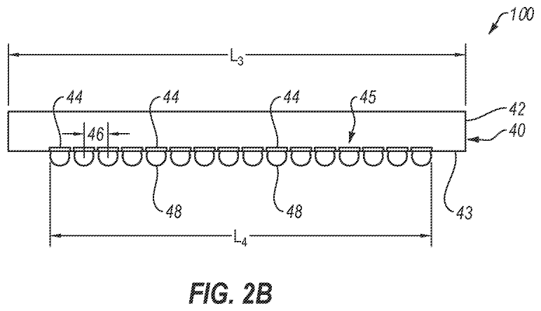

With reference next to FIGS. 2A and 2B, presented therein are a top plan view and a side elevation, respectively, of a second electrical component 40, in accordance with examples of the disclosure. Similar to the first electrical component 20, the second electrical component 40 in accordance with examples of the disclosure may include, but are also in no manner limited to, chips, chiplets, dies, or wafers, without limitation. In some examples, the second electrical component 40 may include, but is in no manner limited to, a digital electrical component (e.g., a digital chip, a digital chiplet, a digital die, a digital wafer).

The second electrical component 40 includes a second electrical component substrate 42, wherein a second electrical component substrate 42 may include any suitable material for electrical components (e.g., silicon). As shown in FIGS. 2A and 2B, the second electrical component substrate 42 includes a second substrate surface 43.

As with the first electrical component 20, the second electrical component 40 may include any number of geometric configurations suitable for electrical components (e.g., square, rectangular, triangular, circular, semi-circular, or oval, without limitation). In some examples, such as is shown in FIG. 2A, the second electrical component 40 has a generally rectangular configuration at least partially defined by a third length L₃ and third width W₃ of the second electrical component substrate 42.

With continued reference to FIG. 2A, the second electrical component 40 includes a number of second connection areas 44 arranged on the second substrate surface 43 of the second electrical component substrate 42, forming a second connection array 45 thereon. The second connection array 45 may include a large number of second connection areas 44 (e.g., hundreds of second connection areas 44, to thousands of second connection areas 44, without limitation). In some examples, the second connection array 45 may be at least partially defined by a fourth length L₄ and a fourth width W₄, wherein the fourth length L₄ and fourth width W₄ are measured along the perimeter of the area on the second substrate surface 43 encompassing the second connection areas 44. Similar to the first electrical component 20, in some examples, wherein the second connection array 45 has a different geometric configuration, alternative dimensions may at least partially define the second connection array 45 (e.g., diameter).

The second connection array 45 may be further defined by a second connection area pitch 46, wherein the second connection area pitch 46 is the distance between the centerpoints of adjacent ones of the second connection areas 44, such as is shown by way of example in FIG. 2B. In some examples, the second connection area pitch 46 may range from about 0.5 μm to about 1.0 mm, such as from about 1.0 μm to about 0.5 mm, or from about 10.0 μm to about 0.05 mm, or from about 10.0 μm to about 40.0 μm. In some other examples, the second connection area pitch 46 may be less than about 100 μm, or less than about 50 μm, or less than about 40 μm, or less than about 20 μm, or less than about 10 μm, or less than about 1 μm. In some examples, the second connection areas 44 may have a very fine pitch (e.g., about a 25 μm pitch (e.g., about 12.5 L/12.5S)).

In some examples, the second connection areas 44 may be formed of a metal (e.g., aluminum, copper). The second connection areas 44 may include masses of connection material 48 formed thereover, such as are shown in FIG. 2B. In some examples, the masses of connection material 48 may include plated bumps having an under-bump metallurgy (e.g., a titanium-copper under-bump metallurgy having a copper layer about 0.4 μm thick over a titanium layer about 0.1 μm thick). In addition, the plated bumps may include a metal diffusion layer having a solder composition formed over the under-bump metallurgy (e.g., a nickel diffusion layer about 3 μm thick deposited on the titanium-copper under-bump metallurgy and having a tin-silver solder composition about 15 μm thick formed thereover). In other examples, the masses of connection material 48 may include micro-copper pillar bumps, also having an under-bump metallurgy (e.g., a titanium-copper under-bump metallurgy having a copper layer about 0.4 μm thick over a titanium layer about 0.1 μm thick). Further, the micro-copper pillar bumps may include a metal conduction layer and a metal diffusion layer having a solder composition formed thereon (e.g., a copper layer about 10 μm thick deposited on the titanium-copper under-bump metallurgy and having a nickel diffusion layer about 3 μm thick and a tin-silver solder composition about 15 μm thick formed thereover). In some examples, the masses of connection material 48 may have a flux (e.g., a no-clean flux) incorporated therein or applied thereover, prior to a mass reflow process.

As shown in the figures, the masses of connection material 48 are formed on the second connection areas 44 of the second electrical component 40, however, in some examples, the masses of connection material 48 may alternatively or additionally be formed on the first connection areas 24 of the first electrical component 20.

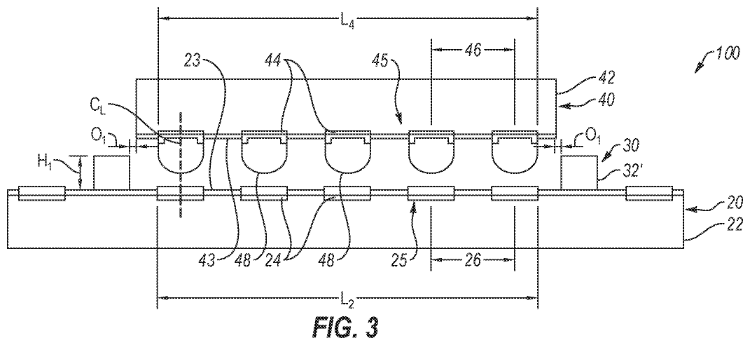

Looking next to FIG. 3, presented therein is a side elevation of the second electrical component 40 prior to placement onto the first electrical component 20, in accordance with examples of the disclosure. As may be seen from FIG. 3, the second electrical component 40 is positioned over the first electrical component 20 such that a center of each of the second connection areas 44, and the masses of connection material 48 formed thereon, are substantially aligned with a center of a corresponding one of the first connection areas 24, such as is illustrated by centerline C_{L}. As further shown in FIG. 3, the first connection area pitch 26 is substantially the same as the second connection area pitch 46, to facilitate substantial center-to-center alignment of the second connection areas 44 over the first connection areas 24. As a non-limiting example, a commercially available high accuracy (e.g., a tolerance of about 1 μm, without limitation) flip chip pick and place device (not shown) may be utilized to effectuate the precision alignment of the second electrical component 40 over the first electrical component 20, as illustrated in FIG. 3.

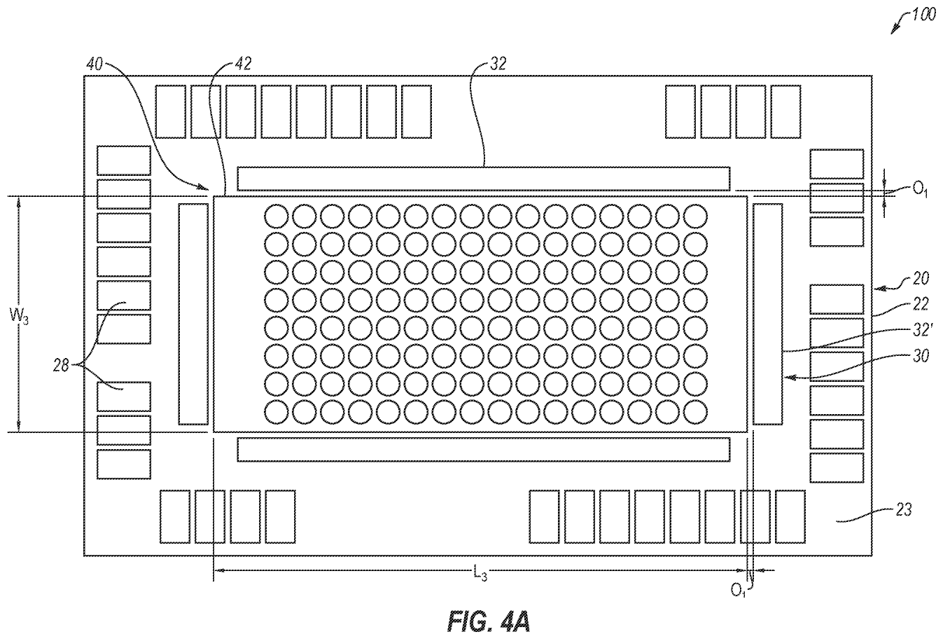

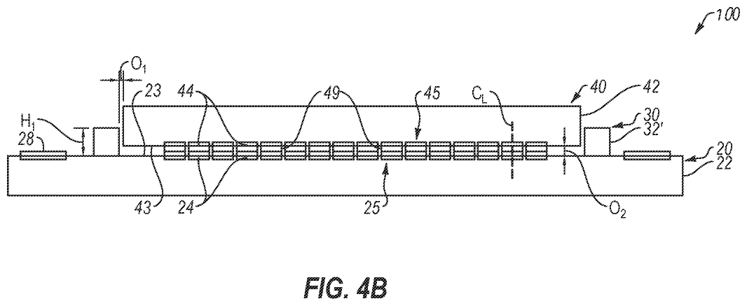

In some examples, the second length L₂ of the first connection array 25 is substantially equal to the fourth length L₄ of the second connection array 45, such as is shown in FIG. 3. Although not shown in the figures, in some examples, the second width W₂ of the first connection array 25 may be substantially equal to the fourth width W₄ of the second connection array 45. A first offset O₁ may be formed between sidewalls of the second electrical component substrate 42 and the sidewalls of the support structures 32, 32′ of the support assembly 30 facing inwardly towards the first connection array 25. More in particular, the first offset O₁ is formed when the second electrical component 40 is positioned onto the first electrical component 20, i.e., when the second electrical component 40 is positioned over the first electrical component 20 in an aligned face-to-face orientation such that the center of each of the second connection areas 44, and the masses of connection material 48 formed thereon, are facing and substantially aligned with the center of a corresponding one of the first connection areas 24, such as is shown in FIG. 3. The third length L₃ and the third width W₃ of the second electrical component substrate 42 of the second electrical component 40 are dimensioned such that when the second electrical component 40 is positioned over the first electrical component 20, the sidewalls of second electrical component substrate 42 are disposed within the sidewalls of the support structures 32, 32′ of the support assembly 30, as shown in FIG. 4A. The first offset O₁ may be in a range of from about 1 μm to about 10 μm, such as from about 1 μm to about 3 μm, or from about 2 μm to about 6 μm, or from about 2 μm to about 4 μm, or from about 2 μm to about 3 μm. In some examples, the first offset O₁ may by substantially uniform between the sidewalls of the second electrical component substrate 42 and the sidewalls of the support structures 32, 32′ of the support assembly 30 facing inwardly towards the first connection array 25. However, in other examples, the first offset O₁ may vary slightly due to manufacturing tolerances.

The first offset O₁ limits a range of movement of the second electrical component 40 relative to the first electrical component 20, and more specifically, the first offset O₁ limits a lateral range of movement of the second connection areas 44 on the second electrical component substrate 42 of the second electrical component 40, when the second electrical component 40 is positioned onto the first electrical component 20 and bounded by the support structures 32, 32′ of the support assembly 30, as shown in FIGS. 4A and 4B.

Turning next to FIGS. 4A and 4B, presented therein are top plan and side elevation views, respectively, of the second electrical component 40 of FIG. 3 after placement onto the first electrical component 20, in accordance with examples of the disclosure. As before, the first offset O₁ is formed between sidewalls of the second electrical component substrate 42 and the sidewalls of the support structures 32, 32′ of the support assembly 30, thereby limiting a lateral range of movement of second electrical component 40 relative to the first electrical component 20 within the boundaries formed by the support structures 32, 32′, during a mass reflow process. In addition, a second offset O₂ may be formed between the first substrate surface 23 and the second substrate surface 43 when the second electrical component 40 is positioned onto the first electrical component 20. The second offset O₂ is less than a first height H₁ of the support structures 32, 32′, such that the support structures 32, 32′ limit a lateral range of movement of the second electrical component 40 when positioned onto the first electrical component 20, as may be seen from FIG. 4B.

As a result of the limitation on the lateral range of movement of the second electrical component 40 by the support structures 32, 32′ of the support assembly 30 while positioned onto the first electrical component 20, the second connection areas 44, and the masses of connection material 48 formed thereon, remain substantially aligned with corresponding ones of the first connection areas 24 during heating and solder reflow. Further, during a solder reflow process, the limited lateral range of movement of the second electrical component 40 bounded by the support structures 32, 32′ allows for the “self-alignment” of the second connection areas 44 with corresponding ones of the first connection areas 24, due to the surface tension forces of the solder while in a liquid state, subsequently forming connections 49 therebetween upon cooling. Further, the limited lateral range of movement of the second electrical component 40 minimizes (e.g., prevents, reduces, without limitation) shorting between adjacent ones of the connections 49 by minimizing (e.g., preventing, reducing, without limitation) contact therebetween while the solder is in a liquified state. Use, here, of the term “minimize” or derivatives thereof is not intended to imply minimum electrical shorting or contact is required, and is merely used here to convey to the reader that reducing contact and electrical shorting is generally desirable. The amount of acceptable contact or electrical shorting depends on specific operating conditions. After cooling, the connections 49 formed between the second connection areas 44 and corresponding ones of the first connection areas 24 are disposed substantially along centerlines C_{L} therebetween, as shown in FIG. 4B.

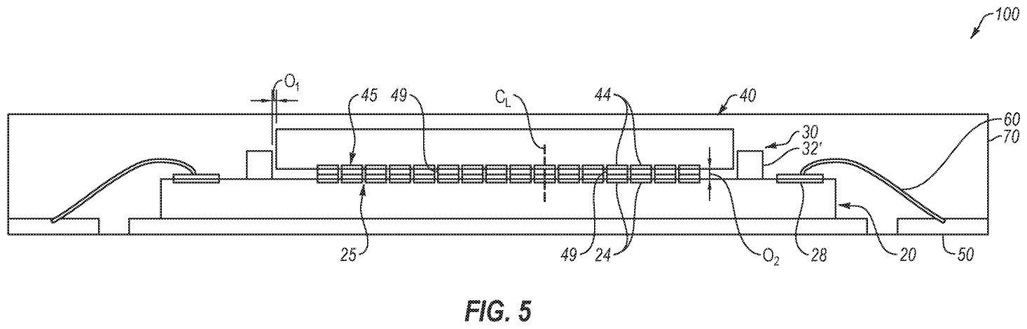

As before, a commercially available high accuracy flip chip pick and place device may be utilized in accordance with examples of the disclosure to position large quantities of second electrical components 40 onto corresponding ones of first electrical components 20, each having a support assembly 30 mounted (e.g., formed, without limitation) thereon. The first and second electrical components 20, 40 are then exposed to elevated temperatures in a mass reflow process, thereby allowing mass production of electrical apparatuses 100 including electrical components having an ultra-fine pitch (e.g., less than about a 10-micron pitch) connected to one another, such as is shown in FIG. 5, while minimizing (e.g., preventing, reducing, without limitation) electrical shorting therein. Use, here, of the term “minimize” or derivatives thereof is not intended to imply minimum electrical shorting is required and is merely used to convey to the reader that reducing electrical shorting is generally desirable. As before, the amount of acceptable electrical shorting depends on specific operating conditions.

FIG. 5 presents a side elevation of an electrical apparatus 100 including electrical components 20, 40 assembled in accordance with examples of the disclosure. The electrical apparatus 100 includes a first electrical component 20 operatively (e.g., electrically, without limitation) connected to a second electrical component 40 via connections 49 formed between corresponding ones of the first connection areas 24 and the second connection areas 44. As may be seen from FIG. 5, as a result of the limited lateral range of movement of the second electrical component 40 permitted by the support structures 32, 32′ and the “self-alignment” of the second connection areas 44 with the first connection areas 24 due to the surface tension forces of the solder while in a liquid state, the connections 49 are substantially aligned between corresponding ones of the of first connection areas 24 and the second connection areas 44 along centerlines C_{L} therebetween. The first electrical component 20 may be mounted to a lead frame 50 (e.g., a QFN lead frame), and connected thereto (e.g., electrically connected) via wire bonds 60 connected between portions of the lead frame 50 and corresponding ones of the wire bond pads 28. In some examples, an overmold 70 may be formed over the first electrical component 20, having the support assembly 30 mounted thereon, the second electrical component 40, the lead frame 50, and wire bonds 60 to protect them from damage.

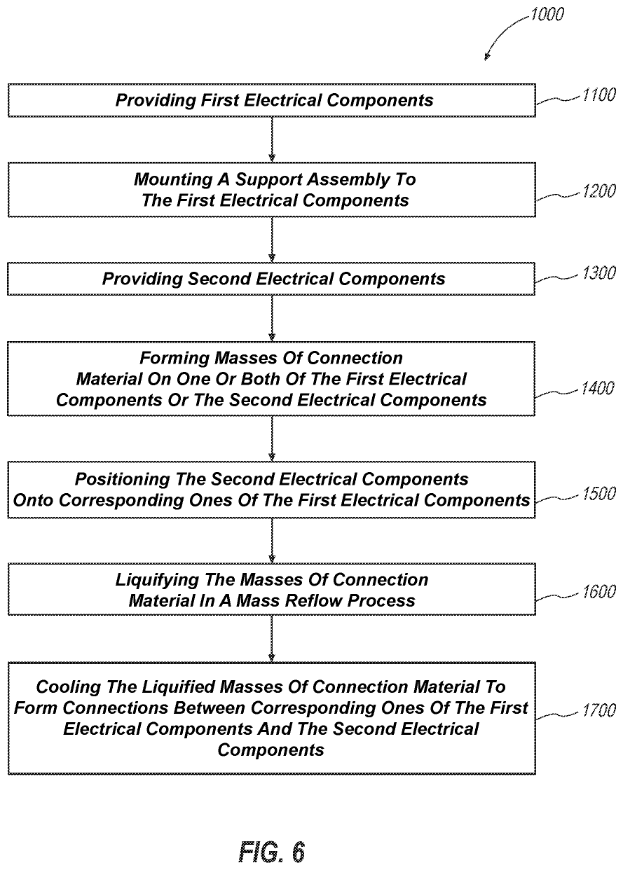

FIG. 6 is a flowchart depicting an example of an illustrative method of alignment of electrical components of an electrical apparatus with a support assembly 1000, in accordance with examples of the disclosure. The method of alignment of electrical components of an electrical apparatus with a support assembly 1000 includes providing first electrical components, as indicated at act 1100. In some examples, a respective first electrical component includes first connection areas disposed thereon in a first connection array.

The method of alignment of electrical components of an electrical apparatus with a support assembly 1000 also includes mounting a support assembly to the first electrical components, as indicated at act 1200. In accordance with examples of the disclosure, the respective support assembly is mounted to a respective first electrical component in an at least partially surrounding relation to the first connection areas disposed thereon in the first connection array. In at least some examples, the support assembly includes one or more support structures (e.g., support structures 32, 32′ as shown in FIGS. 1A and 4A).

With continued reference to FIG. 6, the method of alignment of electrical components of an electrical apparatus with a support assembly 1000 includes providing second electrical components, as indicated at act 1300. Similar to first electrical components, respective second electrical components include second connection areas disposed thereon in a second connection array. The method of alignment of electrical components of an electrical apparatus with a support assembly 1000 also includes forming masses of connection material on one or both of the first electrical components or the second electrical components, as indicated at act 1400. In at least some examples, the act 1400 of forming masses of connection material on one or both of the first electrical components or the second electrical components includes forming masses of connection material on one or both of the first connection areas disposed on the first electrical components or the second connection areas disposed on the second electrical components.

The method of alignment of electrical components of an electrical apparatus with a support assembly 1000 also includes positioning the second electrical components onto corresponding ones of the first electrical components, as indicated at act 1500. More in particular, the act 1500 includes positioning the second electrical components onto corresponding ones of the first electrical components in an aligned face-to-face orientation such that corresponding ones of the second connection areas are facing and substantially aligned with corresponding ones of the first connection areas. In accordance with some examples, the act 1500 of positioning is at least partially defined by a respective support assembly of the respective first electrical component limiting a lateral range of movement of the respective second electrical component positioned thereon by way of a first offset formed between the sidewalls of the support structures of the respective support assembly and the sidewalls of the respective second electrical component positioned within the sidewalls of the support structures of the respective support assembly (e.g., support structures 32, 32′ as shown in FIGS. 1A and 4A). Limiting a lateral range of movement of the respective second electrical component relative to the respective first electrical component permits self-aligning of the corresponding ones of the first connection areas of the respective first electrical component with the corresponding ones of the second connection areas of the respective second electrical component as a result of surface tension forces of the liquified masses of connection material during a mass reflow process.

In some examples, the act 1500 of positioning the second electrical components onto corresponding ones of the first electrical components in an aligned face-to-face orientation such that the corresponding ones of the second connection areas are facing and substantially aligned with corresponding ones of the first connection areas includes positioning the second electrical components onto the corresponding ones of the first electrical components such that the corresponding ones of the second connection areas are substantially aligned with the corresponding ones of the first connection areas with a flip chip pick and place device.

Looking again to FIG. 6, the method of alignment of electrical components of an electrical apparatus with a support assembly 1000 includes liquifying the masses of connection material in a mass reflow process, as indicated at act 1600. Liquifying the masses of connection material in the mass reflow process in accordance with some examples includes liquifying the masses of connection material in the mass reflow process wherein the first electrical components having the corresponding ones of the second electrical components positioned thereon by heating to a temperature of from about 240° C. to about 260° C. In addition, in some examples, liquifying the masses of connection material in the mass reflow process includes liquifying the masses of connection material in the mass reflow process wherein the first electrical components having the corresponding ones of the second electrical components positioned thereon are heated for from about 0.1 minute to about 3 minutes.

Additionally, the method of alignment of electrical components of an electrical apparatus with a support assembly 1000 includes cooling the liquified masses of connection material to form connections between corresponding ones of the first connection areas and the second connection areas, as indicated at act 1700. Forming connections between the corresponding ones of the first connection areas and the second connection areas comprises cooling the liquified masses of connection material, which may be performed by removing the first and second electrical components from a source of heat, and in some examples includes forming connections between the corresponding ones of the first connection areas and the second connection areas upon cooling the liquified masses of connection material to a temperature of from about 20° C. to about 25° C. after the mass reflow process.

In this description, the term “connected” and derivatives thereof may be used to indicate that two or more elements co-operate or interact with each other. When an element is described as being “connected” to another element, then the elements may be in direct physical or electrical contact or there may be intervening elements or layers present.

Additional non-limiting examples of the disclosure include:

Example 1: An apparatus, comprising: first electrical components, a respective first electrical component having first connection areas; second electrical components, a respective second electrical component having second connection areas; support assemblies, a respective support assembly mounted to the respective first electrical component to limit a lateral range of movement of the respective second electrical component relative to the respective first electrical component; and masses of connection material formed on at least one of the first connection areas or the second connection areas to at least partially connect corresponding ones of the first connection areas and the second connection areas.

Example 2: The apparatus according to Example 1, wherein the respective support structure is mounted to the respective first electrical component in an at least partially surrounding relation to the respective second electrical component.

Example 3: The apparatus according to any of Examples 1 and 2, wherein the first connection areas of the respective first electrical component are arranged in a first connection array.

Example 4: The apparatus according to any of Examples 1 through 3, wherein the first connection array is at least partially defined by a first connection area pitch between adjacent ones of the first connection areas of from about 10 microns to about 40 microns.

Example 5: The apparatus according to any of Examples 1 through 4, wherein the respective support structure is mounted to the respective first electrical component in an at least partially surrounding relation to the first connection areas arranged in the first connection array.

Example 6: The apparatus according to any of Examples 1 through 5, wherein the second connection areas of the respective second electrical component are arranged in a second connection array.

Example 7: The apparatus according to any of Examples 1 through 6, wherein the second connection array is at least partially defined by a second connection area pitch between adjacent ones of the second connection areas of from about 10 microns to about 40 microns.

Example 8: The apparatus according to any of Examples 1 through 7, wherein the second connection area pitch is substantially equal to the first connection area pitch.

Example 9: The apparatus according to any of Examples 1 through 8, wherein the support structures are formed of a photodefinable polyimide.

Example 10: The apparatus according to any of Examples 1 through 9, wherein an offset between sidewalls of the respective second electrical component and sidewalls of the respective support structure limits the lateral range of movement of the respective second electrical component.

Example 11: The apparatus according to any of Examples 1 through 10, wherein the offset is from about 1 micron to about 3 microns.

Example 12: The apparatus according to any of Examples 1 through 11, wherein the first electrical components comprise an analog chip, an analog chiplet, an analog die or an analog wafer.

Example 13: The apparatus according to any of Examples 1 through 12, wherein the second electrical components comprise a digital chip, a digital chiplet, a digital die or a digital wafer.

Example 14: A method, comprising: providing first electrical components, wherein a respective first electrical component includes first connection areas disposed thereon in a first connection array; mounting a respective support assembly to respective ones of the first electrical components, wherein the respective support assembly is mounted to the respective first electrical component in an at least partially surrounding relation to the first connection areas disposed thereon in the first connection array; providing second electrical components, wherein a respective second electrical component includes second connection areas disposed thereon in a second connection array; forming masses of connection material on one or both of the first electrical components or the second electrical components; positioning the second electrical components onto corresponding ones of the first electrical components in an aligned face-to-face orientation such that the corresponding ones of the second connection areas are facing and substantially aligned with corresponding ones of the first connection areas, wherein positioning is at least partially defined by the respective support assembly of the respective first electrical component limiting a lateral range of movement of the respective second electrical component positioned thereon; liquifying the masses of connection material in a mass reflow process; and cooling the liquified masses of connection material to form connections between corresponding ones of the first connection areas and the second connection areas.

Example 15: The method according to Example 14, wherein the positioning the second electrical components onto corresponding ones of the first electrical components in an aligned face-to-face orientation such that the corresponding ones of the second connection areas are facing and substantially aligned with corresponding ones of the first connection areas comprises positioning the second electrical components onto the corresponding ones of the first electrical components such that the corresponding ones of the second connection areas are substantially aligned with the corresponding ones of the first connection areas with a flip chip pick and place device.

Example 16: The method according to any of Examples 14 and 15, wherein the limiting the lateral range of movement of the respective second electrical component relative to the respective first electrical component permits self-aligning of the corresponding ones of the first connection areas of the respective first electrical component with the corresponding ones of the second connection areas of the respective second electrical component during the mass reflow process by surface tension forces of the liquified masses of connection material.

Example 17: The method according to any of Examples 14 through 16, wherein the liquifying the masses of connection material in the mass reflow process comprises liquifying the masses of connection material in the mass reflow process wherein the first electrical components having the corresponding ones of the second electrical components positioned thereon by heating to a temperature of from about 240° C. to about 260° C.

Example 18: The method according to any of Examples 14 through 17, wherein the liquifying the masses of connection material in the mass reflow process comprises liquifying the masses of connection material in the mass reflow process wherein the first electrical components having the corresponding ones of the second electrical components positioned thereon are heated from about 0.1 minute to about 3 minutes.

Example 19: The method according to any of Examples 14 through 18, wherein the cooling the liquified masses of connection material to form connections between corresponding ones of the first connection areas and the second connection areas comprises cooling the liquified masses of connection material to a temperature of from about 20° C. to about 25° C. after the mass reflow process to form connections between corresponding ones of the first connection areas and the second connection areas.

Example 20: An apparatus, comprising: a first electrical component having first connection areas arranged thereon in a first connection array; a second electrical component having second connection areas arranged thereon in a second connection array, the second electrical component positioned on the first electrical component such that the second connection areas are substantially aligned with corresponding ones of the first connection areas; a support assembly mounted to the first electrical component in an at least partially surrounding relation to the first connection areas in the first connection array, the support assembly limiting a lateral range of movement of the second electrical component positioned on the first electrical component; and connections between corresponding ones of the first connection areas and the second connection areas formed from masses of connection material on one or both of the first connection areas or the second connection areas.

While certain illustrative examples have been described in connection with the figures, the scope of this disclosure is not limited to those examples explicitly shown and described in this disclosure. Rather, many additions, deletions, and modifications to the examples described in this disclosure may be made to produce examples within the scope of this disclosure, such as those specifically claimed, including legal equivalents. In addition, features from one disclosed example may be combined with features of another disclosed example while still being within the scope of this disclosure.

What is claimed is:

1. An apparatus, comprising:
first electrical components, a respective first electrical component having first connection areas;
second electrical components, a respective second electrical component having second connection areas;
support assemblies, a respective support assembly mounted to the respective first electrical component to limit a lateral range of movement of the respective second electrical component relative to the respective first electrical component; and
masses of connection material formed on at least one of the first connection areas or the second connection areas to at least partially connect corresponding ones of the first connection areas and the second connection areas.

2. The apparatus of claim 1, wherein the respective support structure is mounted to the respective first electrical component in an at least partially surrounding relation to the respective second electrical component.

3. The apparatus of claim 1, wherein the first connection areas of the respective first electrical component are arranged in a first connection array.

4. The apparatus of claim 3, wherein the first connection array is at least partially defined by a first connection area pitch between adjacent ones of the first connection areas of from about 10 microns to about 40 microns.

5. The apparatus of claim 3, wherein the respective support structure is mounted to the respective first electrical component in an at least partially surrounding relation to the first connection areas arranged in the first connection array.

6. The apparatus of claim 4, wherein the second connection areas of the respective second electrical component are arranged in a second connection array.

7. The apparatus of claim 6, wherein the second connection array is at least partially defined by a second connection area pitch between adjacent ones of the second connection areas of from about 10 microns to about 40 microns.

8. The apparatus of claim 7, wherein the second connection area pitch is substantially equal to the first connection area pitch.

9. The apparatus of claim 1, wherein the support structures are formed of a photodefinable polyimide.

10. The apparatus of claim 1, wherein an offset between sidewalls of the respective second electrical component and sidewalls of the respective support structure limits the lateral range of movement of the respective second electrical component.

11. The apparatus of claim 8, wherein the offset is from about 1 micron to about 3 microns.

12. The apparatus of claim 1, wherein the first electrical components comprise an analog chip, an analog chiplet, an analog die or an analog wafer.

13. The apparatus of claim 12, wherein the second electrical components comprise a digital chip, a digital chiplet, a digital die or a digital wafer.

14. A method, comprising:
providing first electrical components, wherein a respective first electrical component includes first connection areas disposed thereon in a first connection array;
mounting a respective support assembly to respective ones of the first electrical components, wherein the respective support assembly is mounted to the respective first electrical component in an at least partially surrounding relation to the first connection areas disposed thereon in the first connection array;
providing second electrical components, wherein a respective second electrical component includes second connection areas disposed thereon in a second connection array;
forming masses of connection material on one or both of the first electrical components or the second electrical components;
positioning the second electrical components onto corresponding ones of the first electrical components in an aligned face-to-face orientation such that the corresponding ones of the second connection areas are facing and substantially aligned with corresponding ones of the first connection areas, wherein positioning is at least partially defined by the respective support assembly of the respective first electrical component limiting a lateral range of movement of the respective second electrical component positioned thereon;
liquifying the masses of connection material in a mass reflow process; and
cooling the liquified masses of connection material to form connections between corresponding ones of the first connection areas and the second connection areas.

15. The method of claim 14, wherein the positioning the second electrical components onto corresponding ones of the first electrical components in an aligned face-to-face orientation such that the corresponding ones of the second connection areas are facing and substantially aligned with corresponding ones of the first connection areas comprises positioning the second electrical components onto the corresponding ones of the first electrical components such that the corresponding ones of the second connection areas are substantially aligned with the corresponding ones of the first connection areas with a flip chip pick and place device.

16. The method of claim 14, wherein the limiting the lateral range of movement of the respective second electrical component relative to the respective first electrical component permits self-aligning of the corresponding ones of the first connection areas of the respective first electrical component with the corresponding ones of the second connection areas of the respective second electrical component during the mass reflow process by surface tension forces of the liquified masses of connection material.

17. The method of claim 14, wherein the liquifying the masses of connection material in the mass reflow process comprises liquifying the masses of connection material in the mass reflow process wherein the first electrical components having the corresponding ones of the second electrical components positioned thereon by heating to a temperature of from about 240° C. to about 260° C.

18. The method of claim 16, wherein the liquifying the masses of connection material in the mass reflow process comprises liquifying the masses of connection material in the mass reflow process wherein the first electrical components having the corresponding ones of the second electrical components positioned thereon are heated from about 0.1 minute to about 3 minutes.

19. The method of claim 14, wherein the cooling the liquified masses of connection material to form connections between corresponding ones of the first connection areas and the second connection areas comprises cooling the liquified masses of connection material to a temperature of from about 20° C. to about 25° C. after the mass reflow process to form connections between corresponding ones of the first connection areas and the second connection areas.

20. An apparatus, comprising:
a first electrical component having first connection areas arranged thereon in a first connection array;
a second electrical component having second connection areas arranged thereon in a second connection array, the second electrical component positioned on the first electrical component such that the second connection areas are substantially aligned with corresponding ones of the first connection areas;
a support assembly mounted to the first electrical component in an at least partially surrounding relation to the first connection areas in the first connection array, the support assembly limiting a lateral range of movement of the second electrical component positioned on the first electrical component; and
connections between corresponding ones of the first connection areas and the second connection areas formed from masses of connection material on one or both of the first connection areas or the second connection areas.
